(19) United States
(12) Patent Application Publication
(10) Pub. No.: US 2010/0097048 A1
(43) Pub. Date: Apr. 22, 2010

(54) PASSIVE DETECTION OF ANALYTES

(76) Inventors: Douglas H. Werner, State College, PA (US); Theresa S. Mayer, Port Matilda, PA (US); Michael J. Roan, Blacksburg, VA (US); Matthew G. Bray, State College, PA (US); Alexey E. Kovalev, Bellefonte, PA (US)

Correspondence Address: GIFFORD, KRASS, SPRINKLE,ANDERSON & CITKOWSKI, P.C, PO BOX 7021, TROY, MI, 48007-7021, US

(21) Appl. No.: 12/521,783

(22) PCT Filed: Jan. 4, 2008
(86) PCT No.: PCT/US08/50267

§ 371 Date: Jun. 30, 2009

Related U.S. Application Data
(60) Provisional application No. 60/883,423, filed on Jan. 4, 2007.

(51) Int. Cl. G01R 19/00

(52) U.S. Cl. 324/76.11

(57) ABSTRACT

A passive element is provided to facilitate passive detection of analytes, such as analytes, using an electromagnetic probe beam. The probe beam may be provided by a radar and/or lidar system. In one example, a passive element comprises a reference dipole and a detection dipole, the detection dipole having an associated analyte-sensitive element, such as a chemoresistive or bioresistive element. When the analyte-sensitive element is in a modified conducting state due to the presence of an analyte, the detection cross section is modified whereas a reference cross section is substantially unchanged by the presence of the analyte. A passive element may comprise a frequency selective surface, for example including a frequency-selective surface (FSS) embedded in a dielectric layer and using an analyte-sensitive impedance layer to modify the electromagnetic absorption properties, allowing analyte detection.

### REFERENCE TO RELATED APPLICATION

This application claims priority from U.S. Provisional Patent Application Ser. No. 60/883,423 filed Jan. 4, 2008, the contents of which is incorporated herein by reference.

### STATEMENT OF GOVERNMENT SUPPORT

This invention was made with government support under Grant No. N00014-05-1-0844, awarded by the Office of Naval Research. The Government has certain rights in the invention.

### FIELD OF THE INVENTION

The present invention relates to the detection of analytes, such as the passive detection of chemical or biological analytes.

### BACKGROUND OF THE INVENTION

Current detection methods and devices for recognizing the presence of analytes generally require the operation of complex, specifically tailored sensing units, electrically connected and repositioned to monitor a target analyte. Current chemical and biological detection apparatus and methods are typically complex, non-deployable, and do not allow of remote monitoring upon deployment,

However, there are many situations where remote detection of analytes is extremely useful, including remote detection of chemical or biological health hazards. Hence, improved detection methods and apparatus are urgently required.

### BRIEF SUMMARY OF THE INVENTION

Embodiments of the present invention include passive elements, such as a passive element including an analyte-sensitive material having electromagnetic absorption properties that are modified by the presence of the analyte. In some examples, the passive element has a first absorption at a detection wavelength that is modified by the presence of an analyte, and a second absorption at a reference wavelength that is substantially independent of the presence or otherwise of the analyte. In some examples, a passive element includes one or more dipoles. In further examples, a passive element includes a FSS (frequency selective surface), a dielectric layer, and an impedance layer, the impedance layer comprising an analyte-sensitive material. In further examples, a passive element comprises a dielectric layer and an analyte-sensitive layer.

A passive element may be formed on a substrate, such as a dielectric substrate such as a polymer sheet. In some examples, a passive element may be part of an apparatus having other functions. For example, passive elements according to embodiments of the present invention may be included in food packaging, tickets (such as transportation tickets, including subway tickets), labels, and the like.

In representative examples, a passive element for assisting detection of an analyte includes a substrate, a first dipole (or detection dipole) supported by the substrate, and an analyte-sensitive element such as a chemoresistive element associated with the first dipole. The analyte-sensitive element may be located proximate the detection dipole, for example proximate to (such as disposed at) an end of a conducting strip. The first dipole and the chemoresistive element cooperatively provide a first absorption cross section at a detection wavelength. The first absorption cross section is correlated with the presence of an analyte, having appreciably different values at one or more detection wavelengths according to whether the analyte is present or absent. The chemoresistive element interacts with the analyte, having an electrical conductivity correlated with the presence of the analyte, so that the first absorption cross section is modified by the presence of the analyte. Optionally, a second dipole (or reference dipole) may be disposed on the surface of the substrate, the second dipole having a second absorption cross section at a reference wavelength. The second absorption cross-section may be substantially independent of the presence of the analyte, allowing an absorption ratio to be determined. The absorption ratio can be determined as the detection wavelength absorption in a ratio with reference wavelength absorption.

The first and second dipoles may each comprise a metal strip or strip of other electrically conducting material. The effective electrical length of the detection dipole can be modified by the chemoresistive element. For example, the electrical length may be extended by the chemoresistive element when the chemoresistive element is in a higher conductivity state.

In some examples, the electrical lengths of reference and detection dipoles are approximately equal when the analyte-sensitive element is in a low conductivity state, or in some examples the electrical lengths are equal when the analyte-sensitive element is in a high conductivity state. The analyte-sensitive element can be placed at or proximate to one end of an elongated detection dipole, so that when conducting the electrical length of the detection dipole is effectively enhanced.

In some examples, detection and reference dipoles are orthogonal, in a cross-dipole configuration. The detection dipole and/or reference dipole may meander over the substrate so as to reduce the overall dimensions (e.g. substrate area) required for the dipole. Dipoles may meander over a substrate, for example so as to reduce the substrate area required.

An analyte-sensitive material, such as a chemoresistive material, may comprise a chemoresistive polymer, and may have a low conductivity state in the absence of the analyte and a high conductivity state in the presence of the analyte. A first absorption cross section and the second absorption cross section may be approximately equal when the chemoresistive element is in the low conductivity state. The low conductivity state of the chemoresistive element may act so as to extend the electrical length of the first dipole.

Terms such as high and low conductivity are relative terms, for example the conductivity of a material in the absence of an analyte may be appreciably higher or lower compared with the conductivity in the presence of the analyte. The “presence” of the analyte refers to an analyte being present in a concentration or other measure sufficient to have an appreciable effect on one or more properties of the passive element. For example, a low (or high) conductivity state may be achieved when the analyte is present in a concentration above a detection threshold. Such thresholds in relation to chemoresistive materials are known in the art.

Other examples of the present invention include a passive element for assisting detection of an analyte comprising a frequency selective surface (FSS) formed from FSS elements such as conducting patches, a dielectric layer, and an impedance layer, the dielectric layer being located between the resistive layer and the FSS in a sandwich structure. FSS elements may be conducting patches arranged in a periodic array, and may be separated in the plane of the FSS by the same dielectric material as used in the dielectric layer. The impedance layer comprises an analyte-sensitive material, such as a chemoresistive material, so that the absorption properties of the passive element are sensitive to the presence of an analyte through changes in the electrical conductivity of the analyte-sensitive material. For example, an impedance layer may comprise a chemo resistive polymer.

An impedance layer may comprise a plurality of sub-layers, including a first sub-layer formed from a chemoresistive material, and a second sub-layer comprising a non-chemoresistive conducting material. Variations in the sheet resistance of the impedance layer enable the passive element to have absorption properties at a detection wavelength that are correlated with the presence (or otherwise) of the analyte.

The detection wavelength may be a resonant frequency of the FSS, and may be an IR wavelength. In some examples, the passive element may have a high, possibly maximum, absorption when the sheet resistance of the impedance layer is approximately equal to the impedance of free space. In some configurations, this may be in the presence of the analyte, but in other examples it may be in the absence of the analyte, the analyte then acting to reduce absorption which may then be detected. The dielectric layer may have a thickness of approximately one quarter of the detection wavelength, and the FSS may be resonant at the detection wavelength.

In some examples, a back-to-back configuration is used, the passive element further including a second dielectric layer so that the FSS is sandwiched between first and second dielectric layers, and a second impedance layer. In this example, the impedance layers are the outer layers of the device, exposed to analytes in the environment. The second dielectric layer is located between the FSS and the second impedance layer. The analyte may be detectable from determination of the absorption properties of either face of the passive element.

A method for remote passive detection of an analyte comprises providing a passive element, the passive element including a chemoresistive material, determining first absorption of the passive element at a detection wavelength, determining a second absorption of the passive element at a reference wavelength from a passive element, and detecting the analyte from a comparison of the first absorption and the second absorption. The passive element may include a detection dipole and a reference dipole, the detection dipole having an associated chemoresistive element. In some examples, the passive element includes a sandwich structure in the form of a sheet having opposed faces, including a frequency selective surface (FSS), dielectric layers each side of the FSS, and impedance layer at each of the opposed faces. The sheet thickness may be approximately half the detection wavelength, each dielectric layer being one quarter wavelength thick, plus the thicknesses of the FSS and two impedance layers.

### BRIEF DESCRIPTION OF THE DRAWINGS

FIG. 1 shows a conventional Salisbury Screen Absorber (SSA) design;

FIG. 2 shows the reflectivity of the SSA design shown in FIG. 1;

FIGS. 3A-3B show horizontal and vertical cross-sections of a passive element including an FSS (frequency selective screen) for the remote detection of analytes;

FIG. 4 shows the reflectivity of a passive element versus the sheet resistance of an impedance layer;

FIG. 5 shows the reflectivity of a passive element at a detection frequency of 1.5 microns versus the sheet resistance of the conductive polymer.

FIG. 6 shows an SSA design with a split impedance layer, comprising a sublayer having an analyte-sensitive conductivity and a sublayer having a fixed conductivity;

FIG. 7 shows the reflectivity of the SSA with a split impedance layer at a detection frequency of 1.5 microns versus the impedance of a chemoresistive sub-layer for a range of fixed sublayer impedances;

FIG. 8 shows an extended range of the data of FIG. 7;

FIG. 9 shows a linear dipole passive element useful for detecting analytes;

FIG. 10 shows the Radar Cross Section (RCS) of the dipole passive element illustrated in FIG. 9 for the “on” and “off” states (high and low conductivity) of the analyte-sensitive element;

FIG. 11 shows an end-loaded miniature polarization independent cross-dipole passive element useful for detecting analytes;

FIG. 12 shows the wavelength normalized RCS of the cross-dipole passive element shown in FIG. 11 as the conductivity of the analyte-sensitive element is varied;

FIG. 13 shows a miniaturized polarization independent cross-dipole passive element with optimized geometry via a Genetic Algorithm (GA);

FIG. 14 shows a method in which the dipole passive elements are dropped from a UAV into a chemical or biological plume and then remotely monitored by a radar or lidar system;

FIGS. 15A-B show an array of FSS elements in the form of concentric rings of analyte-sensitive and fixed conductivity materials;

FIGS. 16A-B show a further example comprising a dielectric film and an analyte-sensitive film;

FIGS. 17A-B illustrate properties of a fabricated FSS-based passive element.

### DETAILED DESCRIPTION OF THE PREFERRED EMBODIMENT

The present invention relates to the passive detection of analytes. Examples include methods and apparatus for detection of analytes using passive elements, which may be in the form of chaff deployed into the atmosphere. A passive element may be remotely monitored using an electromagnetic probe beam, for example using either a radar or lidar system. Embodiments of the present invention include methods and apparatus facilitating the remote passive detection of analytes. In some examples, passive elements including an FSS and/or dipoles are used.

Embodiments of the present invention include methods and apparatus for remote detection of analytes using passive elements, such as chaff elements which may be deployed into a region desired to be monitored for an analyte. Examples also include methods and apparatus wherein a passive element is used to remotely detect the presence of an analyte, for example in conjunction with a remote radiation source such as a radar or lidar radiation source. Passive elements may be highly transportable, for example deployable within an area suspected of containing analytes using such deployment means as ballistic, rocket, aircraft and/or UAV deployment.

A particular example is an passive element including an FSS for the remote passive detection of analytes using IR radiation. In some examples, a dual-wavelength IR laser is used to measures the IR reflectivity of passive elements at reference and detection wavelengths. For example, a first IR wavelength may be used for detection and a second IR wavelength can be used with a higher reflectivity from the passive element and used as a reference wavelength. By determining a ratio of reference and detection absorption (or, equivalently, reflection) improved sensitivity analyte detection is provided.

In further examples, a passive element may comprise a dipole for remote passive detection of analytes. In some examples, a passive element may comprise a detection dipole and a reference dipole. The resonance frequency of a detector dipole changes in the presence of an analyte, whereas the resonance frequency of a reference dipole is substantially unchanged by the presence of the analyte. The reference dipole may be a metallic reference dipole, and the detection dipole may include a metallic dipole associated with a chemoresistive element. A passive element may be configured so that the reference and detection dipoles are resonant at substantially the same frequency in the absence of an analyte.

A chemoresistive material can be an analyte-sensitive material that changes conductivity in the presence of an analyte, for example due to a chemical or biological interaction with the analyte. Biological analytes may include pathogens such as bacteria, fungi, viruses, proteins, prions, and the like. An analyte-sensitive material may comprise chemical and/or biological receptors for a target analyte. For convenience, many examples described herein are described in terms of chemoresistive materials, having a conductivity (or resistance) sensitive to the presence of an analyte. However, other analyte-sensitive materials may be used in such examples, for example both chemical and biological analyte-sensitive materials. In some cases, an analyte-sensitive element may include multiple components, for example a first component having a first response to an analyte, and a second component having an electrical conductivity that is correlated with the magnitude of the first response. For example, the first response may include release of chemicals, modification of luminescence (e.g. fluorescence quenching), and the like.

An analyte-sensitive element may comprise an analyte-sensitive material having appreciable change in electrical resistance as a function of analyte concentration. The analyte-sensitive material may directly interact with the analyte, or the response may be mediated by other components. Many chemoresistive materials are known in the art, including chemoresistive polymers such as polythiophenes, polyanilenes (PANIs), polypyrroles, and the like. Analyte-sensitive materials may also include any chemoselective material having a property, such as resistance, that is modified in the presence of a selected analyte. In general, where examples discuss chemoresistive materials, these examples may be readily configured to include a bioresistive materials having an appreciable change in conductivity as a function of biological analyte concentration.

A passive element may change from a state of higher absorption at a detection wavelength with no analyte present to a state of high reflectivity (low absorption) in the presence of an analyte, allowing determination of whether or not the analyte is present. In the case of dipole passive elements, the resonant frequency of a detection dipole can shifts in the presence of an analyte, whereas that of a reference dipole may be substantially unaffected by the presence of the analyte. A shift in detection dipole resonance frequency relative the reference dipole resonance frequency can be remotely detected, for example via a radar or lidar system. Similarly, an FSS-based passive element may change absorption properties at a detection wavelength in the presence of the analyte, possibly correlated with analyte concentration, whereas an absorption at a reference wavelength is substantially independent of the local analyte concentration.

Embodiments of the present invention allow long-range, possibly eye-safe detection of analytes. In some examples, analyte detection is achieved from a change in the near infrared (NIR) reflection of passive elements. A passive element may comprise an analyte-sensitive medium, such as a chemoresistive conducting polymer (CP) layer, separated by a quarter-wavelength thickness dielectric layer from a metallo-dielectric frequency selective surface (FSS). The FSS may be configured for high, possibly maximum, substantially angle-independent reflection at the detection and reflection wavelengths.

### Further Examples of FSS-based Passive Elements

In particular examples, the conductivity of an analyte-sensitive material (such as a chemoresistive polymer) at the detection wavelength may increase from substantially insulating to appreciably conductive in the presence of an analyte, resulting in a strong absorption of the energy reflected from the passive element at the detection wavelength. An initially (no analyte) highly reflective surface may become strongly absorbing the detection wavelength, while retaining a high reflection at a reference wavelength (for example, one approximately double the detection wavelength). Alternative FSS-based designs can be used to fabricate passive elements that transition from transmissive to reflective with exposure to an analyte.

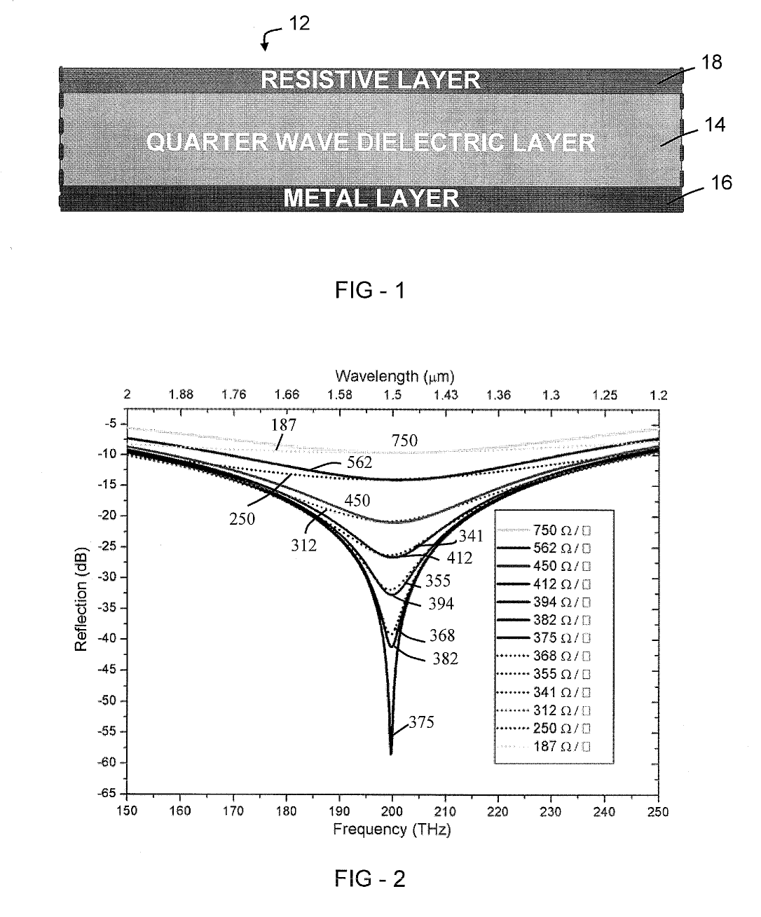

FIG. 1 shows a schematic diagram of a conventional Salisbury screen absorber (SSA) 12. The SSA 12 consists of a quarter-wavelength dielectric layer 14 having first and second sides. A metallic backing layer 16 is disposed on one side, and an impedance layer 18 is disposed on the other side. Conventionally, the impedance layer has a conductivity that is not modified by the presence of an analyte.

When an incoming electromagnetic wave is incident normally to the impedance layer 18, it reflects off of the metallic backing 16 setting up a standing wave in the dielectric layer 14. The maximum value of this wave occurs at the impedance layer 18, which absorbs the incoming energy.

FIG. 2 shows a plot of frequency versus wavelength for the reflectivity of the SSA design 12, shown in FIG. 1. For this design, the dielectric layer 14 is chosen to be a quarter-wavelength at a design wavelength (operating wavelength) of 1.5 microns. Multiple curves are shown in FIG. 2 representing differing values of sheet resistance for the impedance layer 18. Maximum absorption occurs when the impedance of the impedance layer 18 is approximately the impedance of free space, or about 377 ohms.

In some examples of the present invention, the impedance layer has a sheet resistance that is modified by the presence of the analyte, and is between approximately 300 ohms/square and approximately 450 ohms/square, more particularly between approximately 350 ohms/square and 400 ohms/square, more particularly approximately the impedance of free space, either in the presence or absence of the analyte.

Hence, changing the sheet resistance of the impedance layer 18 can significantly affect the absorption. If the absorption change is readily detectable, the absorption state of absorber 12 may be effectively turned “off” and “on”.

However, a simple planar metal backing layer produces deep nulls in reflection at certain incident angles, which produces large changes in the reflected power as angular orientation changes relative to an incident probe beam. This increases the probability of a false alarm, as reflection nulls may be indistinguishable from an absorption triggered by the presence of an analyte. However, some examples of the present invention include a planar metal or other conducting backing layer, a dielectric layer, and an analyte-sensitive impedance layer.

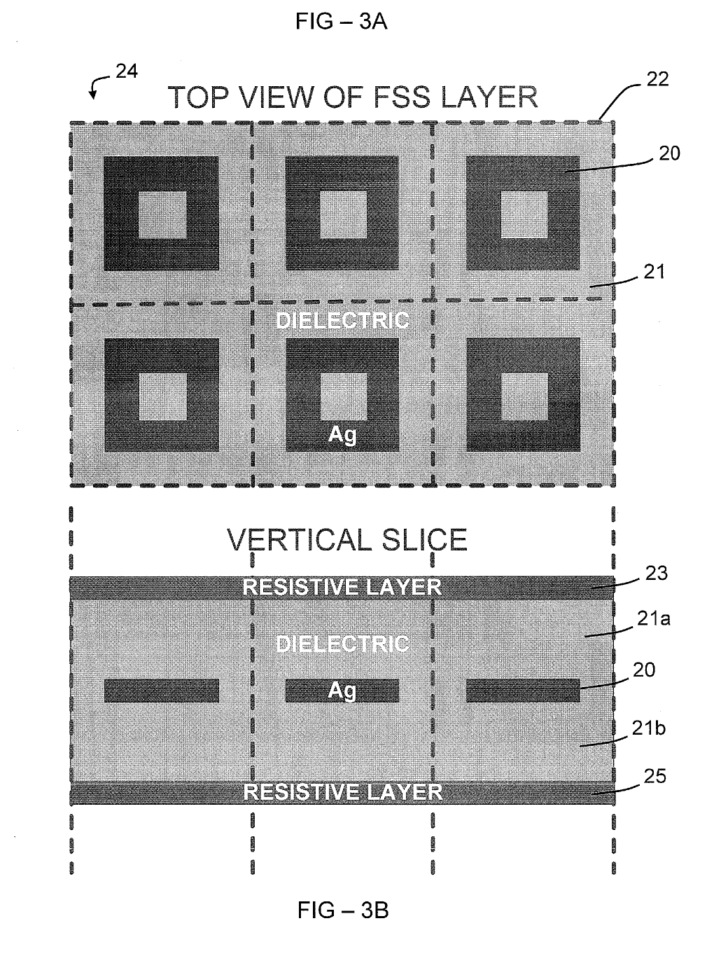

FIGS. 3A-3B show horizontal and vertical cross-sections of a passive element design for the remote detection of analytes. From FIG. 3B, the passive element 24 somewhat resembles two SSAs 12 placed back to back with the metal backing layer (layer 16 of FIG. 1) replaced by a Frequency Selective Surface (FSS) 20.

A view of the FSS elements 20 is shown at the top of FIG. 3, in this example having a square ring shape, having a square outer perimeter with a square void in the center. Other solid and ring shapes may be used, including other geometric forms such as squares and rectangular patches. The dotted lines in this figure represent a unit cell repeat and assist aligning the two views, and need not correspond to any physical structure. The FSS elements 20 may be tiled over part of or the entire surface of a passive element 24. The FSS 20 can be designed to have a high reflectivity at the detection and reference wavelengths as well as transmissive away from these wavelengths. The passive element further includes a dielectric material 21 and first and second impedance layers (labeled resistance layers on the FIGS. 23 and 25 respectively. The dielectric material forms first and second dielectric layers (21a and 21b ) between the FSS and the first and second impedance layers respectively. In some examples, the dielectric layers 21a and 21b are approximately one quarter of a detection wavelength.

The novel design of the passive element 24 allows it to behave as an absorber for electromagnetic radiation incident from either side, giving a double-sided response, and doubling sensitivity in some applications, in particular when the passive element is deployed as chaff. Further, the FSS 20 allows a reduction in directional scattering that would be produced by a conventional SSA with an electrically large ground plane.

In some examples, the second dielectric layer 21a and second impedance layer 25 may be omitted, and a substrate used instead, the FSS being supported by the substrate. FSS elements may be formed from any conducting material, such as metal or conducting polymer. FSS element shapes may be rings (circular, square as in the present example, other geometric shape), patches (squares, circles, other shapes), or other forms. Arrays may be doubly periodic along orthogonal axes, radially periodic, periodic along non-orthogonal axes, or otherwise configured.

In some examples, some or all of the FSS elements may comprise an analyte-sensitive material, for example in configurations in which the second dielectric and impedance layers are omitted and the FSS elements are accessible by the analyte.

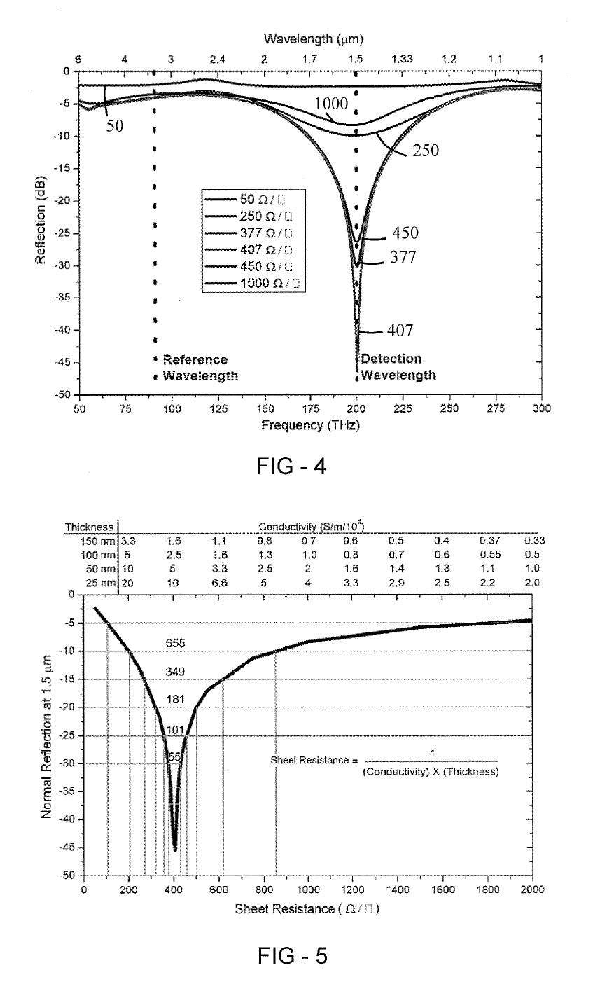

FIG. 4 shows a plot illustrating the reflectivity of the passive element 24 as a function of sheet resistance the impedance layer. The detection wavelength is located within the absorption band of the passive element. Maximum absorption when the impedance layer has an impedance approximately equal to the impedance of free space. In this case this is not exactly 377 ohms because of the finite impedance layer and additional resistance loading from the metallic FSS. As the sheet resistance of the impedance layer is increased or decreased from near the impedance of free space, the absorber becomes more reflective.

A passive element can be fabricated in which the sheet resistance of the impedance layer (or impedance layer resistance) is modified by the presence of an analyte. As the impedance layer resistance varies, absorption at the detection frequency also changes, indicating the presence of an analyte. A reference wavelength can be selected away from the absorption band, having a relatively constant reflection even when the impedance layer resistance varies. Properties at a reference wavelength, such as absorption, can be used as a reference for the detection band, for example for ratiometric determination of absorption, and further to verify the presence of the passive element.

The sheet resistance of the impedance layer may include contributions from a plurality of sub-layers, including sub-layers having analyte-sensitive conductivity and other sub-layers not having analyte-sensitive conductivity.

Hence, an impedance layer need not be a single homogeneous layer, though it could be. An impedance layer may include a plurality of sub-layers.

In some examples, an impedance layer may include (or support) a sensitization layer. A sensitization layer responds to an analyte in such a way as to modify an electrical conductivity. The chemical species modifying the conductivity of an analyte-sensitive material may be provided by a sensitization layer in response to the analyte to be detected.

FIG. 5 is a plot showing the reflectivity of the passive element 24 at a detection frequency of 1.5 microns versus the impedance layer resistance. Superimposed on the curve is a range of impedance layer resistance, centered about the minimum, providing a certain level of absorption. For example, about 55 ohms per square is the full range upon which the absorption band is 30 dB down. The conductivity ranges are also shown in FIG. 5. The impedance layer resistance is inversely proportional to the conductivity multiplied by the thickness of the impedance layer. The table associated with the graph shows an axis for conductivity with different impedance layer thicknesses corresponding to the impedance layer resistance axis on the bottom. The range of impedance layer resistance where a large absorption occurs is relatively small.

There may be practical difficulties in manufacturing a chemoresistive impedance layer, such as a chemoresistive polymer film, having a sheet resistance approximately equal to free space or otherwise chosen to enhance absorption.

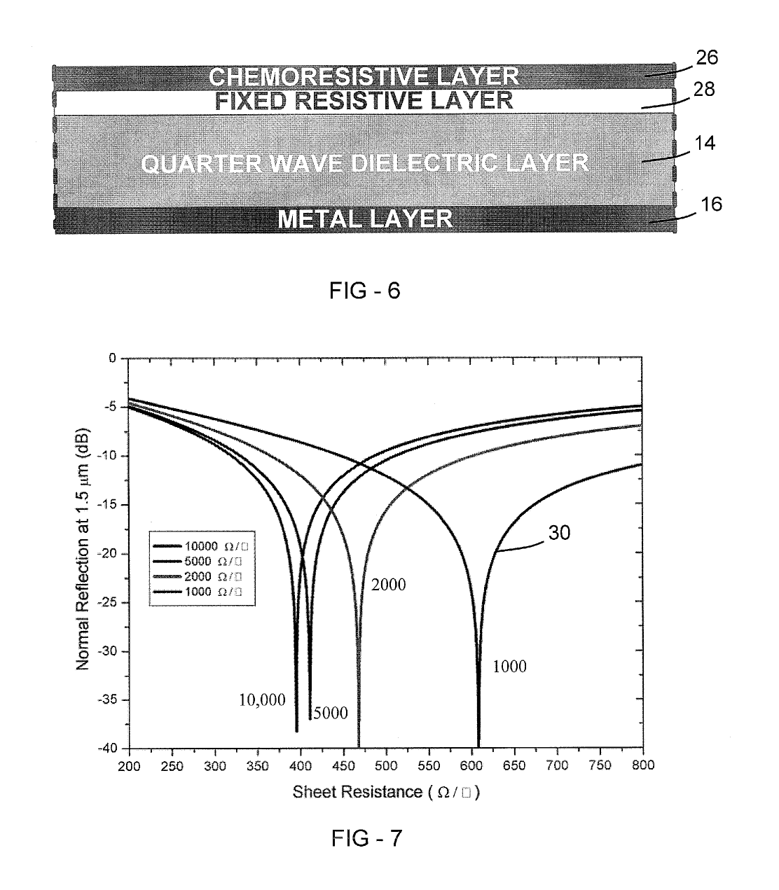

FIG. 6 shows a novel configuration for an impedance layer. In this example, the impedance layer comprises two sub-layers. The lower layer 28 need not be chemoresistive, allowing a much greater range of available material choices for this layer. This layer may also be referred to as the fixed resistive layer, though the resistance may vary due to external parameters such as temperature. The top layer 26, which is exposed to the environment, is a chemoresistive layer having a conductivity (or sheet resistance) that changes in the presence of the analyte. The overall impedance layer resistance is determined by the parallel contributions from the two sub-layers, the fixed resistive layer and the chemoresistive layer.

FIG. 7 shows the reflection coefficient of a passive element with normal excitation at a design frequency of 1.5 microns versus the sheet resistance of the chemoresistive layer. The different curves represent different sheet resistance values for the fixed resistance sub-layer. The plot illustrates that with an impedance layer resistance of 10000 ohms per square, which is nearly free space, the passive element behaves as if it has just one resistive layer. As the sheet resistance of the fixed resistive layer is increased, the curve shifts up in sheet resistance. The behavior of this passive element is similar in form that oft a conventional SSA.

For instance, curve 30 in FIG. 7 shows that the minimum occurs when the sheet resistance of the chemoresistive layer is about 600 ohms per square. This design has a fixed resistive layer with a resistance of 1000 ohms per square. These two resistance values in parallel equal 375 ohms per square or approximately the impedance of free space.

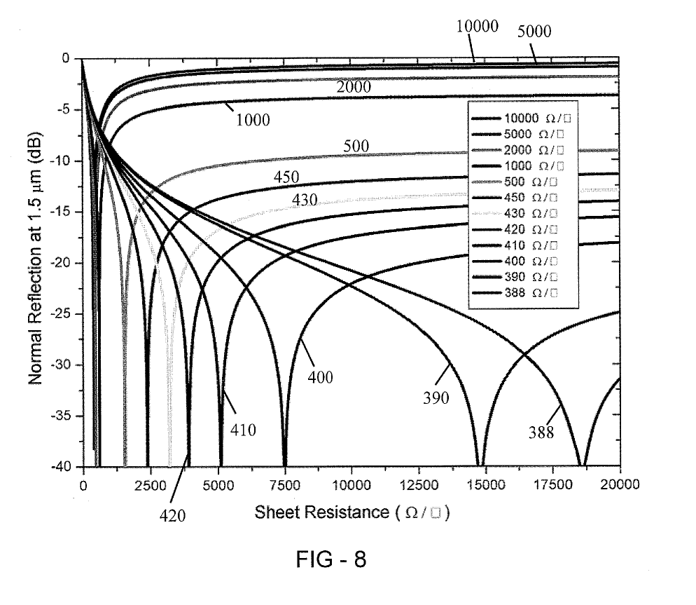

FIG. 8 shows a plot showing an extended range with differing values for the fixed resistive layer. The active “switching” ranges increase as the sheet resistance of the fixed resistive layer approaches the impedance of free space. If the sheet resistance of fixed resistive layer was further reduced, the minimum could be missed and the absorber could perform in a non-optimized manner because the total resistance could never equal that of free space.

Hence, an example passive element includes a NIR-FSS, dielectric layer having a thickness approximately one quarter that of the detection wavelength, an impedance layer including a chemoresistive polymer. Modeled spectra showed reflected power versus wavelength in the absence and presence of an analyte, with a highly reflective state (low absorption) for both the reference and detection wavelengths went the analyte is absent, and a low reflection (absorbing) state at the detection wavelength when the analyte is present. In this example, the passive element remains reflective at the reference wavelength. A passive element may be configured and operated in two different modes, e.g. changing from an absorbing to a highly reflective state or a highly reflective state to an absorbing state (at the detection wavelength) when exposed to an analyte.

An example passive element comprises a thin analyte-sensitive layer, such as an analyte-sensitive conducting polymer, a dielectric layer having an approximately quarter-wavelength (λ/4) thickness at the detection frequency, and an FSS. An incident electromagnetic beam reflects from the FSS, setting up a standing wave in the dielectric layer with maximum intensity at the analyte-sensitive layer. High reflection at the detection and reference wavelengths may be obtained if the analyte-sensitive layer has low conductivity. Absorption increases as sheet resistance of the analyte-sensitive layer falls from a high value to the impedance of free space (377 Ω/□), where reflection approaches zero at the detection wavelength (e.g. less than −20 dB). However, reflection may still be detected at the reference wavelength.

Examples of the present invention include a passive element including an FSS, for example an FSS comprising a doubly periodic array of metallic screen elements with shape and periodicity configured to give a reflecting surface at the detection wavelength. The FSS may be configured to further give a reflecting surface at a reference wavelength.

Examples passive elements were designed having a detection wavelength of 1.55 microns and a reference wavelength of 3.37 microns. However, these wavelengths are exemplary and not limiting. A strong omni-directional reflection, for example less than −3 dB loss independent of incident angle, can be obtained. The metal screen elements of an FSS may be configured with a center-to-center distance along orthogonal directions of approximately λ/2, which is approximately 775 nm for a detection wavelength of 1.55 microns.

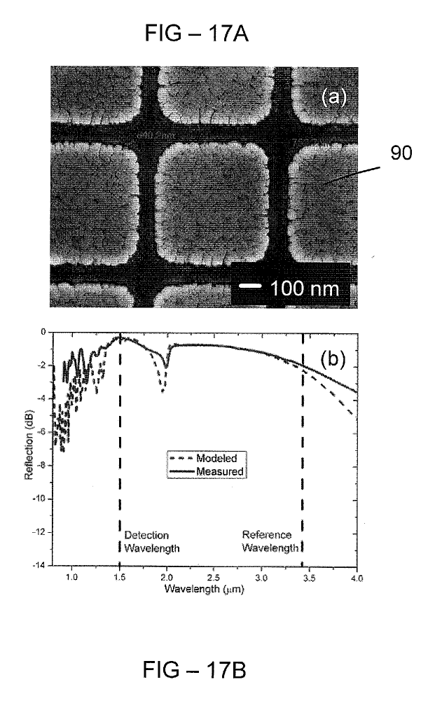

An example passive element was fabricated having 640×640 nm square metal patch elements with a center-to-center spacing of 750 nm. The dielectric layer was a 170 nm thickness layer of silicon nitride (Si₃N₄). Greater than 60% and 80% reflection of the incident optical power was observed at detection and reference wavelengths, respectively. The reflected power was generally insensitive of incident angle from normal incidence to a maximum achieved measurement angle of 30°. A microscopy image is discussed further below at FIG. 17A.

In other modes of operation, the passive element may be configured to be absorbing at the detection wavelength in the absence of analyte, for example near an absorption peak. The presence of analyte then becomes more reflective in the presence of the analyte. For example, a chemoresistive layer may have a sheet resistance approximately equal to the impedance of free space in the absence of an analyte. Analyte-induced fall in impedance (or in other approaches, increase in impedance) then increases reflection. For example, as the conductivity of the chemoresistive layer increases beyond the maximum absorption point, layer reflection increases and the layer approximates a highly-reflective metal sheet. The signal-to-noise of this approach may exceed using a high-impedance film, particularly if a reference probe beam is not used, but the reflection may not be as angle-independent. However, achieving low impedance chemoresistive films may require a greater film thickness, with a corresponding decrease in response time. A multi-layer film may be used to reduce such problems.

### Example Passive Elements Including a Dipole

Further embodiments of the present invention include a dipole passive element, namely a passive element including at least one dipole for analyte detection. Remote passive detection of analytes is possible using dipole passive elements.

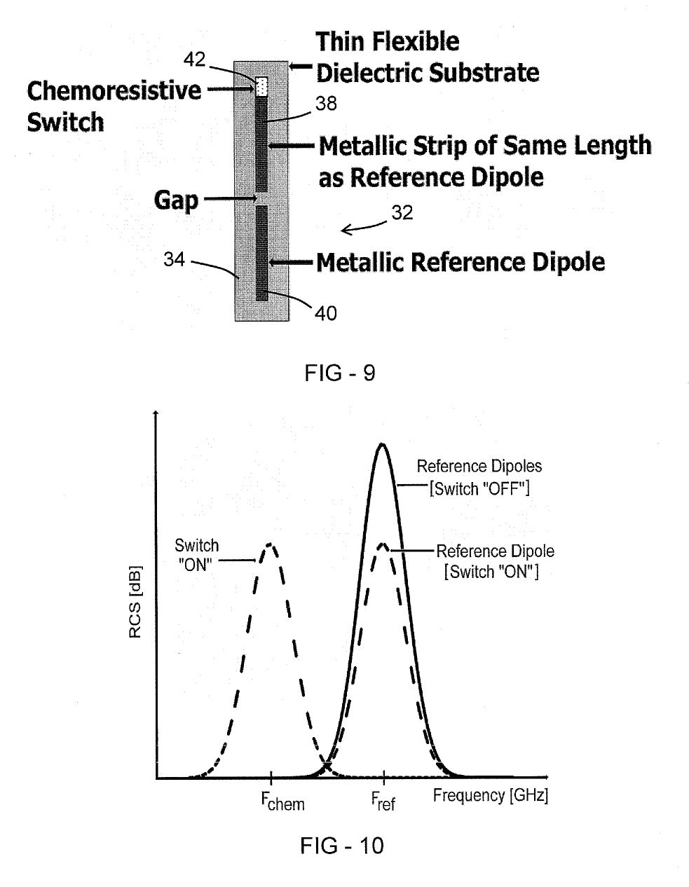

FIG. 9 shows a schematic diagram of a passive element 32. In this example, the passive element 32 comprises a thin flexible dielectric substrate 34 upon which two substantially rectangular metallic dipoles 36 are disposed. For example, metal strips may be printed or otherwise disposed on the substrate. The passive element includes a reference dipole 38 and a detection dipole 40. The reference dipole 38 is a thin rectangular strip of a material having a conductivity substantially independent of the presence or absence of the analyte. For example, the reference dipole may be a metal strip, a non-chemoresistive conducting polymer, or other material. The detection dipole 40 comprises a rectangular strip of metal, in this example approximately the same length as the reference dipole 38. A chemoresistive element 42 is disposed at one end of the detection dipole 48.

When exposed to the analyte, the chemoresistive element 42 changes from a low conductivity state to high conductivity state (or, in other examples, vice versa). When the chemoresistive element is in the low conductivity state, the combination of detection dipole and chemoresistive element has the same absorption cross section as the reference dipole. When the chemoresistive element is in a state of high conductivity, the chemoresistive element acts so as to effectively increase the electrical length of the detection dipole 40, so that peak absorption cross section for the detection dipole then shifts to a lower frequency. Using a radar wavelength as the detection wavelength, the absorption cross section may be termed a radar cross-section (RCS).

FIG. 10 is a plot showing the RCS of a dipole passive element such as illustrated in FIG. 9. In the “off” state, corresponding to low conductivity of the chemoresistive element, both reference and detection dipoles have the same RCS. In the presence of the analyte, the chemoresistive element achieves a high conductivity state (which may be termed turning “on”), which shifts the detection dipole RCS peak to a lower frequency than that of the reference dipole.

Standard linear dipoles in general have a fairly broadband RCS. Most radar systems in military and civilian use today have a usable bandwidth that are comparable to or slightly greater than the standard dipole. This makes the detection of the two dipole states difficult using conventional radar systems.

One method of reducing the bandwidth of a dipole is by making an electrically small element. When the electrical length of the structure is reduced below a half-wavelength, the bandwidth of the element decreases. Hence, an improved passive element includes a detection dipole having an electrical length approximately equal to or less than half the detection wavelength. An improved detection method includes using a detection wavelength at least approximately twice the length of the detection dipole.

Further, in improved dipole passive elements according to examples of the present invention, the electrical length of the detection dipole is less than the detection wavelength, for example less than or approximately equal to half the wavelength, in some examples approximately equal or less than ⅕, and in further examples approximately equal or less than 1/10 the detection wavelength.

An improved dipole passive element according to an embodiment of the present invention includes a detection dipole that is elongated with first and second ends, and an analyte-sensitive element, such as a chemoresistive element, placed proximate to (and in some examples at) one end thereof. Example passive elements include an electrically small dipole (compared with the detection wavelength) having an analyte-sensitive load disposed at the end of the dipole.

The dipole passive element 32, shown in FIG. 9, has polarization dependent absorption properties. The RCS response in FIG. 10 is obtained when the electric field of the interrogating electromagnetic radiation is polarized parallel to the dipole. As the electric field is rotated towards an orientation orthogonal to the dipole, the RCS response is lowered to the point upon which very little energy is backscattered. With this condition, a radar system cannot differentiate between the “on” and “off” state of the chemoresistive element. To reduce the polarization dependence, detection and reference dipoles may be disposed substantially orthogonal to each other, resulting in a cross dipole passive element.

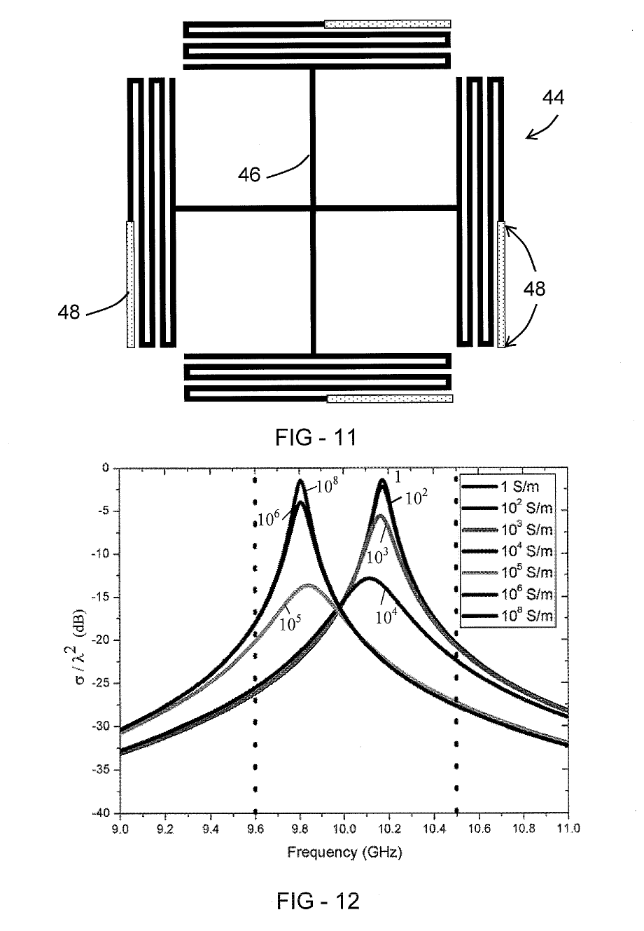

FIG. 11 shows an end-loaded cross-dipole passive element 44 which may be used to facilitate detection of analytes. The lines 46 in this figure represent metallic strip-lines and the lines 48 represent the analyte-sensitive elements, in this example chemoresistive elements. The chemoresistive elements are located at the distal ends of the pattern, relative to the center, and are located between the indicated arrows. The meandering (folded) metallic strip lines 46 at the ends of the dipole greatly reduce the overall dimensions (e.g. the required area on a substrate) for the dipole, and also reduces the bandwidth. For this example, the entire element may only be 3.2 mm by 3.2 mm square, or approximately one tenth of a wavelength square. Hence, an improved cross-dipole configuration comprises meandering conducting tracks, and further includes an analyte-sensitive elements at the distal ends of tracks.

The length of the chemoresistive element 48 may be chosen to switch the peak RCS response of the passive element 44 to within a few percent of its operating frequency. For example, the passive element 44 can be designed to have an off state at 10.2 GHz and an on state at 9.8 GHz. This frequency range falls within the detectable range of conventional X-band radar systems.

A passive element may include cross-dipole configurations for both reference and detection dipoles. A passive element may be configured to have similar absorption cross sections at reference and detection wavelengths for either the analyte-sensitive elements being in a high or low conductivity state.

FIG. 12 shows a plot of the wavelength normalized RCS of the cross-dipole passive element 44 shown in FIG. 11 as a function of the conductivity of the chemoresistive element. As the conductivity of the chemoresistive element is increased from a low conductivity, the RCS response of the passive element changes from an “off” state to an “on” state.

Another approach of making an electrically small dipole is to vary the dipole geometry over the entire length of the dipole. By meandering a metallic strip-line dipole over the substrate, better control over the radiation properties of the passive element can be obtained. Designing such structures heuristically can be difficult, so an optimization technique such as a Genetic Algorithm (GA) may be used.

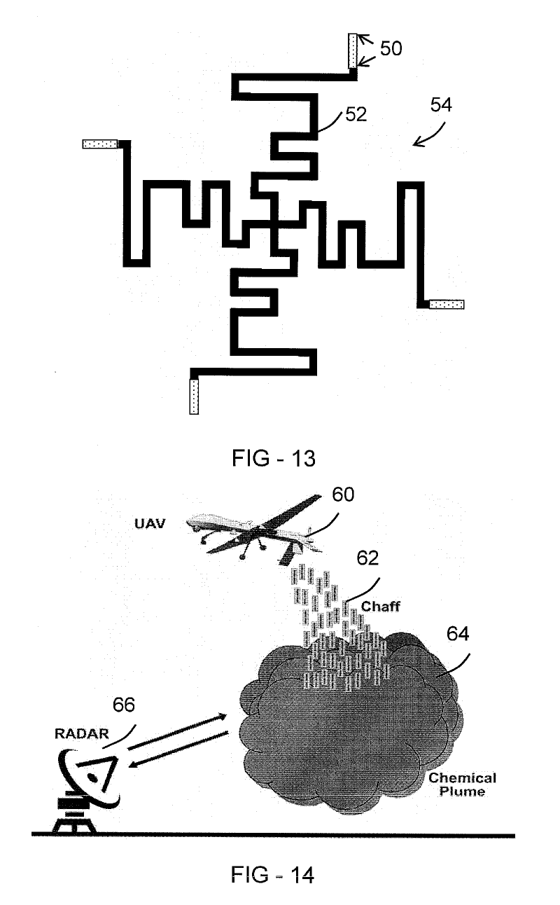

FIG. 13 shows a cross-dipole passive element 54 designed to operate at X-band having a geometry that was optimized using a genetic algorithm. The lines 46 in this figure represent metallic strip lines and the lines 48 represent the chemoresistive elements. The chemoresistive elements are located at the distal ends of the pattern, relative to the center, and are located between the indicated arrows.

FIG. 14 shows an example approach in which the passive elements are used for the remote passive detection of an analyte, such as a chemical or biological agent. An unmanned aerial vehicle (UAV) 60 is positioned above an area suspected to contain the analyte. The UAV then disperses the passive elements into the suspect area 64. A remote radar system 66 is used to detect the presence or absence of the analyte from the response of the passive elements. Other radiation sources may be used. For example, the state of the passive elements can be determined using by a radar or lidar system.

Example Passive Elements Including an FSS in Part Formed from an Analyte-Sensitive Material

A further example of an improved passive element comprises a frequency selective surface (FSS) that includes repeating patterns of at least two species of patch elements. In some examples, a repeating pattern of a first patch element is resonant at the detection frequency, and a repeating pattern of the second patch element is resonant at a reference wavelengths. The first patch elements comprise a chemoresistive element.

In representative examples, a novel passive element comprises patch elements that are concentric rings that provide a nearly omni-directional reflection response. A first ring-shaped patch element comprises a chemoresistive material, and a second ring-shaped patch element comprises a non-chemoresistive material, such as metal. The first and second patch elements may be arranged as concentric rings. For example, the larger diameter ring-shaped patch element may be metal, such as silver, and the smaller diameter ring-shaped patch element may comprise a chemoresistive material, such as a polymer. A doubly periodic array of non-chemoresistive rings is resonant at the reference wavelength, and is reflective with or without analyte present at the reference wavelength. A doubly periodic array of chemoresistive rings transition becomes resonant as conductivity of the chemoresistive material falls in the presence of an analyte. Patch elements may be supported by a substrate, and optionally coated with a superstrate.

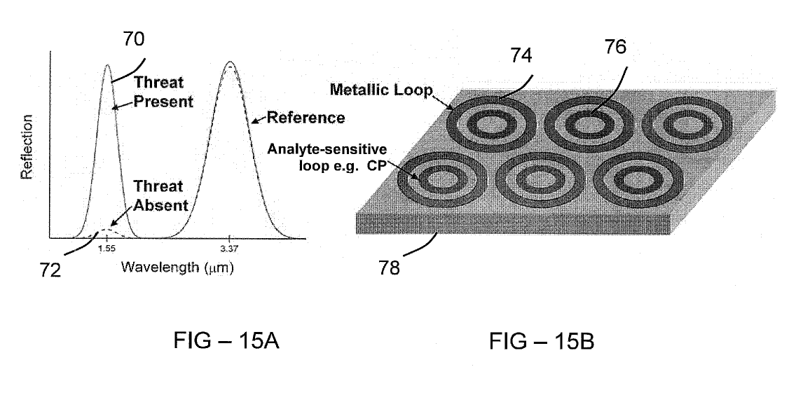

FIG. 15A shows an illustration of the reflected power spectrum obtained using concentric ring patch elements, in this case metal rings and chemoresistive conducting polymer rings. The passive element transitions from transmissive (dashed line 72) to highly reflective (solid line 70) in the presence of an analyte.

FIG. 15B is a schematic showing doubly-periodic concentric ring FSS that includes metallic rings 74 and concentric chemoresistive conducting polymer rings 76 supported on a substrate 78.

An improved passive element include an FSS comprising first FSS elements and second FSS elements, the first FSS elements having an electrical conductivity substantially independent of the presence of the analyte, the second FSS elements having an electrical conductivity correlated with the presence of the analyte. An analyte may be detected using a detection wavelength resonant on the second FSS elements in a conducting state, and a reference wavelength resonant on the first FSS elements.

### Two-Layer Passive Element

In a further example of the present invention, a passive element such as a chaff element comprises two layers. The first layer is a layer of dielectric which is approximately a half-wavelength long at the detection wavelength. This dielectric layer forms a bandpass filter at the detection frequency, where incoming waves pass through the device at the detection frequency and are reflected outside this region at the reference wavelength. In this example, the reference wavelength is longer than the detection wavelength. An analyte-sensitive material, such as a chemoresistive conductive polymer, is deposited on one or both sides of the half-wave dielectric slab. When the analyte-sensitive material has low electrical conductivity, the half-wavelength filter passes waves incoming at the detection frequency. When the analyte-sensitive material is in a conducting state, the reflection properties of the filter are changed, and incoming waves are reflected at the detection frequency indicated the presence of a chemical agent.

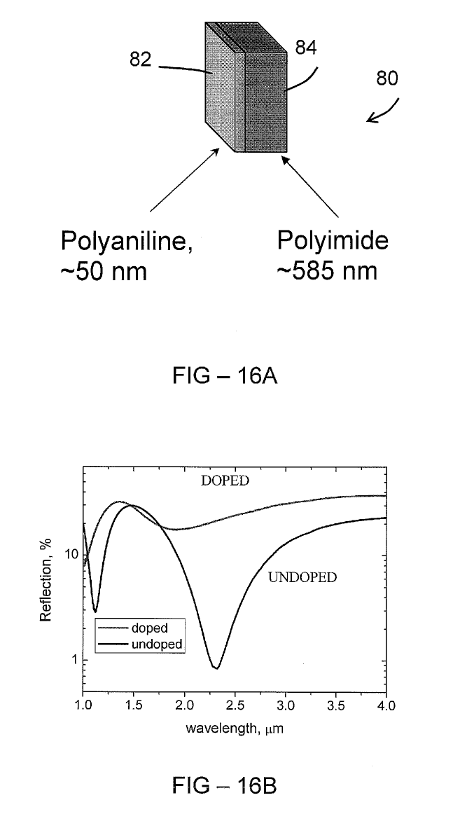

FIG. 16A shows a schematic diagram of the aforementioned device 80, designed for a detection wavelength of 2.25 microns. The device comprises a dielectric layer 84 and an analyte-sensitive layer 82. In this example, the dielectric layer was a 585 nm thick layer of polyimide with a 50 nm layer of a conducting polymer (in this example polyaniline) deposited on a surface thereof. This device was fabricated, and properties measured using a FTIR.

FIG. 16B shows the resulting reflection measurements. At a detection wavelength of 2.25 microns, when the conductive polyaniline is undoped, there is a null in the reflection response due to the half-wavelength filter. When the polyaniline is doped, due to the presence of a chemical analyte, the device becomes reflective at the detection wavelength. Better performance may be obtained with analyte-sensitive layers, such as chemoresistive conducting polymer, on both sides of the dielectric layer.

Hence, an example passive element comprises a dielectric layer having a thickness approximately one half the detection wavelength, and an analyte-sensitive layer having a thickness substantially less than the dielectric layer. For example, the analyte-sensitive layer may have a thickness of approximately ⅕ or less, or approximately 1/10 or less of the dielectric layer thickness. A further example comprises a dielectric layer having first and second surfaces, and first and second analyte-sensitive layers disposed on the first and second surfaces respectively. The analyte-sensitive layers may each have a thickness substantially less than the dielectric layer.

In further examples, the analyte-sensitive layer indicated in FIG. 16A may comprise a plurality of sublayers, for example as described above in relation to FIG. 6. An analyte-sensitive sublayer may be disposed on a conducting sub-layer having an impedance substantially independent of the presence of the analyte, the sublayers being disposed on a dielectric layer. Hence, an improved passive element may comprise a dielectric layer having a thickness approximately one half the detection (or measurement) wavelength, and an impedance layer having a thickness substantially less than the dielectric layer, the impedance layer including an analyte-sensitive sublayer and a conducting sub-layer having an impedance substantially independent of the presence of the analyte

### Example NIR FSS Response

An example NIR FSS was fabricated, and its response evaluated. FIG. 17A illustrates a microscopy image of an example FSS. The square metal patch elements 90 are approximately 640×640 nm, and the center-to-center spacing between patches is 750 nm. FIG. 17B shows the reflected power in the NIR (near-IR) measured at 25 degrees from normal incidence. The measured value shown by the solid line is below −1 dB at the 1.55 micron detection wavelength and approximately −2 dB at the 3.37 micron reference wavelength, corresponding to greater than 60% and 80% reflection of the incident power. The measured value corresponds very well to the modeled response given by the dashed line in FIG. 17B.

Devices were fabricated using Chemical Vapor Deposition (CVD). In one approach, CVD was used to fabricate a dielectric stack comprising a release layer and a silicon nitride Si₃N₄ dielectric layer on a silicon handle wafer. A metal NIR-FSS can be patterned on the dielectric layer either using deep-UV projection photolithography, step-and-flash nanoimprint lithography, or other high throughput optical or nanoimprint lithography methods, which can also be used pattern analyte-sensitive films by direct exposure or by pattern transfer using RIE. A second dielectric layer may be deposited on the FSS, and analyte-sensitive impedance layers deposited to obtain a double-sided response to the analyte. A fabricated structure can be released from the handle wafer after fabrication.

Passive elements were fabricated comprising a NIR-FSS, Si₃N₄ quarter wavelength dielectric layer, and a conducting polymer (PANT) impedance layer. Hydrochloric (HCl) acid vapor was detected at 3000 ppm, the HCl vapor diffusing into an undoped insulating polymer layer and reducing the sheet resistance. At a detection wavelength of 1.7 microns, the electromagnetic response of a passive element transitioned from highly reflecting (−2 dB) to strongly absorbing (−22 dB) in less than 3 sec. Passive elements exhibited rapid detection response (t<3 sec) at acid vapor concentrations of less than 10 g/m³.

### Double-Sided Response

In some examples, such as shown in FIG. 3, a symmetrical design is provided, in which similar response properties from both sides of the passive element are obtained. Any embodiment described herein may be configured to have a double sided response, which increases detection sensitivity by a factor of about two, requiring half the number of passive elements for the same response as conventional passive elements. The signal-to-noise ratio may be improved by receiving a strong reflection rather than attempting to detect a strong absorption in the presence of an analyte.

### Analytes

Analytes which may be detected include chemical or biological agents, toxic industrial chemicals (TICs), and volatile organic compounds (VOCs).

A passive element may be used to detect a particular analyte, or class of analytes (such as chemical or biological materials). In some cases, a passive element may include two or more types of analyte-sensitive materials, and be used to detect the presence of more than one analyte or type of analyte.

### Analyte-Sensitive Materials

Analyte-sensitive materials, such as chemoresistive or bioresistive materials, include materials that changes conductivity in the presence of the analyte. Examples include conducting polymers having an electrical conductivity modified by the presence of an analyte, for example, decreasing electrical conductivity when the conducting polymer is exposed to the analyte.

Other materials include chemoresistive materials such as nanostructured semiconductors, other nanostructured conductors such as metals, chemical field effect transistors, composites of a polymer and electrically conducting particles, such as polymers which swell in the presence of an analyte, and carbon-containing particles.

Analyte-sensitive materials include materials that change conductivity state in the presence of certain chemical or biological analytes, which may generally be termed chemoresistive materials, such as conductive polymers, including derivatives of polythiophenes, polypyrrole and polyaniline. The conductivity of such materials can be enhanced by building percolation threshold composites that include carbon black, nanowires and carbon nanotubes. A chemically sensitive field effect transistor (ChemFET) may also be used.

A chemoresistive element may include a receptor layer for selectively binding analytes, such as biological or chemical receptors.

Examples described herein include passive elements, which do not require a dedicated power supply for operation. However, in some examples an electronic circuit may be included in an improved device, and may derive power from the interrogating RF or other ambient electromagnetic radiation. Example electronic circuits may include sensors for other ambient parameters, such as temperature. In some examples, luminescence (such as fluorescence) of a material is modified (e.g. quenched) by an analyte, modifying electrical conductivity of a photoresistive layer.

Chemoresistive materials that can be used in embodiments of the present invention include organic semiconductors (organic or inorganic), semiconductor polymers, other polymers, metalorganics (such as phthalocyanines). Chemoresistive materials that can be used include those used in conventional chemoresistive gas sensors. Example materials that may be used in chemoresistive elements, possibly after functionalization, include: nanostructured materials such as metal or semiconductor nanowires, metal or semiconductor nanoparticles; forms of carbon such as nanotubes and fullerenes; polymers such as conducting polymers, including poly(acetylene), poly(pyrrole), poly(thiophene), poly(bisthiophene phenylene), poly(aniline), poly(fluorene), poly(3-alkylthiophene), polynaphthalene, poly(p-phenylene sulfide), and poly(p-phenylene vinylene), polyphenylene, other polyarylenes, poly(arylene vinylene) such as poly(phenylene vinylene), poly(arylene ethynylene)), other conjugated polymers, and the like and derivatives thereof; ladder polymers, macrocycles such as phthalocyanine and porphyrin, and polymers therof, and the like.

Further example chemoresistive materials include conducting polymers having an electrical conductivity modified by the presence of an analyte, for example decreasing when the conducting polymer is exposed to the analyte. Other example chemoresistive materials include nanostructured semiconductors, other nanostructured conductors such as metals, chemical field effect transistors, composites of a polymer and electrically conducting particles (such as polymers which swell in the presence of an analyte, and carbon-containing particles).

Chemoresistive conducting polymers known in the art can be used in embodiments of the present invention.

A lower on-state conductivity may require a thicker layer of conducting polymer, such as tens of microns and thicker. The surface area of a chemoresistive film can be increased by surface topography (such as grooves), porous films, and the like, to increase surface area and sensitivity to an analyte. For example, porous conducting polymer films based on fabrics or fibers can be used. In other examples, multilayer films including chemoresistive sub-layers, and conducting but non-chemoresistive sub-layers, may be used to obtain resistance changes of an impedance layer that are in a lower range of resistances than can readily be obtained using conventional techniques.

In some examples, chemoresistive elements produce large changes in RF conductivity in response to analytes, while exhibiting low dielectric loss for the RF frequency bands of interest. Different physical mechanisms can be used, such as a chemically sensitive conducting polymer, a percolation threshold polymer/metal nanowire composite, or a chemically sensitive field effect transistor (ChemFET).

Examples of the present invention include chemically sensitive conducting polymers as chemoresistive elements in switches. Suitable polymers are disclosed in U.S. Pat. No. 6,323,309 to Swager et al. For example, the DC conduction pathway along a polymer backbone can be broken upon binding of an analyte, corresponding to a switch formed from the polymer conducting or on when a target analyte is not present and non-conducting or off when the target analyte is present. The RF properties of a chemoresistive polymer may not be identical to the DC properties, but operational devices are possible. Polymers may be also be lossy, requiring a trade-off of sensitivity and other operational parameters.

A chemoresistive element may comprise a plurality of parallel-connected polymer wires. A single conduction channel within a chemoresistive element can provide molecular level sensitivity in some examples.

Chemoresistive conducting polymer switches may show resistance changes that depend on the exposure concentration and time. Non-ideal concentration and time dependent resistance changes can be corrected by, for example, using a system modeling algorithm which may be part of a detection system. Further, patterning processes used to fabricate chemoresistive polymer switches may be used to modify chemoresistive or other polymer properties.

Percolation threshold polymer/nanowire composites can also be used as a sensor switch. It is possible to achieve large changes in DC conductivity by incorporating carbon black within a nonconductive organic polymer matrix such that the carbon black forms an interconnected matrix at the percolation threshold for conduction (See for example U.S. Pat. No. 6,773,926, to Lewis and co-inventors, and Dai et al., Sensors and sensor arrays based on conjugated polymers and carbon nanotubes, Pure Appl. Chem., Vol. 74, No. 9, pp. 1753-1772, 2002). The organic polymer matrix undergoes a conformational change (i.e., swelling) in the presence of a particular analyte or class of analytes. The swelling causes the carbon black matrix to disconnect, which results in a significant drop in the dc conductivity of the sensor.

Suitable nonconductive polymer matrices are known for a range of organic vapors, and more recently for several nerve agent simulants and explosives. Similar percolation threshold sensors that incorporate template synthesized gold metal nanowires should have improved RF properties (i.e., conductivity and loss) well suited for an apparatus according to the present invention.

For example, metal nanowires can be self assembled into dendritically connected networks using an external field applied directly to the patterned FSS prior to applying the nonconductive polymer across the entire RFSS. Although this element fabrication may require a multi-step fabrication approach, it eliminates the need for patterning a chemically sensitive polymer. The resistance change of such percolation threshold elements may be more abrupt than the chemically sensitive chemoresistive polymers described previously. This type of non-ideal response can also be modeled to improve analytical accuracy.

Chemically sensitive field effect transistors can also be used as an RFSS sensor switch. Operation involves modulating the carrier density in nominally undoped silicon (or amorphous silicon; a-Si) through analyte binding, which induces a charge at the gate of the transistor. In conventional ChemFET technology, the channel resistance is modulated by changing the amount of inversion charge underneath the gate. Here, the introduction of carriers in the semiconductor changes the plasma frequency of the material and hence the RF conductivity of the material. In fact, this concept can be used for an improved RFSS design by optically exciting, for example using IR radiation, regions, such as masked regions, of a planar slab of intrinsic silicon. In this example, a FSS responsive to an external condition (IR radiation) is provided.

A layer of analyte-sensitive material may be porous, for example to increase response speed by allowing an analyte to more rapidly reach the interior of the layer. Various chemically sensitive gate materials can be used, including polymers and self-assembled monolayers with chemical recognition units.

### Applications

Examples of the present invention include passive elements in the form of chaff that may be deployed into the atmosphere so as to detect analytes within the atmosphere. For example, deployment may include dropping from an airplane, firing a projectile (which may later open to allow chaff to emerge), and the like.

Applications further include passive elements configured to allow detection of food contamination by remote inspection. A passive element may be included in a food package, or other package, and interrogated using radiation passing through a window transparent at the detection wavelength. Further applications include passive elements according to embodiments of the present invention used for detecting leaks in chemical plants, chemical plume detection, detecting contaminants in water or other fluids, and the like.

Other applications include remote monitoring for the presence or spread of crop diseases by aircraft or by satellite. Passive elements may be dispersed on the ground, and interrogated by electromagnetic radiation from airborne or space vehicles.

In some cases, a material having an electrical resistance sensitive to radiation, including ionizing radiation, elementary particles, and the like, may be used in place of a chemoresistive material in the examples described. Applications of such devices and methods using such devices include radioactive analyte detection.

Bioresistive elements may include a molecular recognition layer to bind to or otherwise interact with a target biological analyte.

### Detection Methods

The presence of an analyte may be detected by dispersing passive elements in the form of chaff into a region to be monitored, such the atmosphere, and remotely monitoring reflected radiation at a detection wavelength and optionally also a reference wavelength. Absorption at a detection wavelength may be determined relative to absorption at the reference wavelength. A passive element may be micron-scale, for example in the form of a sheet having no dimension greater than approximately than 1 millimeter. In some examples, square chaff elements where fabricated with a dimension of 250×250 microns.

Methods according to the present invention include providing a passive element according to an embodiment of the present invention, directing a probe electromagnetic beam towards the passive element, and detecting an analyte using the electromagnetic response of the passive element to the probe beam. The probe beam may be substantially monochromatic at a detection wavelength, dichromatic including detection and reference wavelengths, or comprise a bandwidth including the detection and optionally also the reference wavelengths. The source of the probe beam may comprise a radar antenna, laser, light emitting diode, lamp, or other source of electromagnetic radiation. The source may be a handheld device, component of a process monitoring system, or other device.

Passive elements in the form of chaff may be dispersed into a suspicious chemical or biological cloud, or other region desired to be monitored. Deployment may include dropping from a plane, firing projectiles including passive elements in a releasable form, and the like. The dimensions of the passive elements may be small compared with the detection wavelength.

In some examples, a dual-wavelength electromagnetic source, such as a radar source or laser, is used to measure the absorption cross section of a passive element at detection and reference wavelengths. An absorption cross section ratio allows improved accuracy of analyte detection. In representative examples, a reference absorption cross section is substantially unaffected by presence of the analyte, whereas a detection absorption cross section is sensitive to the presence of analyte. A ratio of the reference and detection cross sections is then sensitive to analyte presence, and allows compensation for common conditions such as external attenuations, temperature, and other factors. In particular, this approach may be used with FSS-based passive element designs where the FSS is resonant at approximately the detection wavelength.

Embodiments of the present invention provide long-range, eye-safe detection of analytes. In some examples, a passive element comprises a chemically sensitized (or biologically sensitized) chemoresistive layer, a quarter-wavelength thick dielectric layer, and a FSS reflector. The passive elements transition from highly reflective to highly absorbing (or vice versa) at a detection wavelength with exposure to the analyte, while remaining highly reflective at a reference wavelength. Example passive elements including an FSS were both fabricated and modeled using a detection wavelength of 1.55 microns, and a more than a 99% change in the reflected signal at the detection wavelength was observed.

Further embodiments include passive elements configured to operate at other wavelengths, including optical, IR, THz, microwave, or radar wavelengths.

Further examples

Embodiments of the present invention include dipole and FSS-based passive element that facilitate remote passive detection of analytes, including analytes.

Passive elements may be disposed on or comprise a substrate, for example a dielectric substrate. A substrate may be a polymer, paper (including card), other fibrous material, glass, ceramic, or other material. A substrate may comprise part of another apparatus, such as a package or housing for another component, a support structure for a building, vehicle component, chemical processing apparatus component, ticket, credit card, identity card, or other component.

According to one representative aspect of the present invention, a dipole passive element for remote passive detection of analytes is provided. A dipole passive element has a substrate having a body with a surface and a pair of dipoles on the surface. A reference dipole of the pair of dipoles has a first radar cross section and a detection dipole of the pair of dipoles has a second radar cross section. A chemoresistive element is positioned at the end of the detection dipole, end-loading the detection dipole when in a conducting state, such that the detection radar cross section shifts down in frequency relative to the reference radar cross section when the chemoresistive element is exposed to the analyte.

According to another aspect of the present invention, a FSS-based passive element facilitating remote passive detection of analytes such as analytes is disclosed. An example passive element has a body having a plurality of frequency selective surface elements embedded within the body, the FSS being resonant at an IR wavelength. Dielectric layers surround the plurality of frequency selective surface elements. An impedance layer covers the dielectric layer such that the analyte-sensitive sheet resistance of the impedance layer changes a level of absorption for the passive element, which can be used to detect the presence of an analyte.

According to further aspects of the present invention, novel methods for remote passive detection of analytes, such as analytes, using a dipole passive element are disclosed. In an example method, a passive element includes a substrate having a body with a surface, a reference dipole with a reference absorption cross section disposed on the surface, and a detection dipole with a detection absorption cross section disposed on the surface. A chemoresistive element is provided on the end of the detection dipole. The method further includes exposing the dipole passive element to the analyte, and detecting a change in the detection absorption cross section relative to the reference radar cross section. This absorption ratio (or, equivalently, reflectance ratio) may be sensitive to the presence of analyte due to conductivity changes in the chemoresistive element, so that determination of the absorption ratio facilitates detection of the analyte.

According to another aspect of the present invention, novel methods for remote passive detection of analytes using a passive element including an FSS are disclosed. In an example method, a passive element is provided including a body having a plurality of frequency selective surfaces elements embedded within the body, a dielectric layer, and an impedance layer. One or more dielectric layers may surround the plurality of frequency selective surface elements. A dielectric layer is located between the impedance layer and the FSS. A method further includes determining absorption of the passive element at a detection wavelength, which may be an IR wavelength though this is not limiting. A change in the sheet resistance of the impedance layer, due to inclusion of a chemoresistive material, modifies the absorption of passive element and allows detection of the analyte. In further examples, absorption at a detection wavelength may be compared with detection at a reference wavelength. The reference wavelength may be approximately twice (approximately some other multiple such as four times) the detection wavelength.

Examples of the present application include the use of a reference dipole on the same substrate as a detection dipole. The detection dipole properties are appreciably changed in the presence of the analyte, whereas the properties of the reference dipole are substantially unchanged. Determination of for example, an absorption ratio allows accurate detection of the analyte.

Other examples include a double-sided “back-to-back” configuration, having a resistive layer/dielectric/FSS (frequency selective surface)/dielectric/resistive layer structure. This structure has advantages of being an absorber on both sides of the structure, and improved directional properties. This configuration is useful for IR applications, where the overall thickness is less than for radar applications.

In other examples, an FSS is used in combination with a dielectric layer and a chemoresistive material as a component of a conducting sheet (impedance layer) in a multilayer structure. A multilayer structure in the form chemoresistive sheet/dielectric layer/FSS has advantages as fine patterning of the chemoresistive material is not required. Hence, there are advantages in manufacturing simplicity in providing the chemoresistive material as a uniform sheet as compared to a component of a microstructured FSS (frequency selective surface).

Some examples of the present invention include an impedance layer comprising multiple sub-layer combination of normal resistive (i.e. not analyte-sensitive) and chemoresistive material sub-layers. The combined (effectively parallel) resistance of the two films can be readily optimized for maximum (or near maximum) analyte sensitivity. At some sheet resistance values, particularly close to the impedance of free space, small changes in resistance lead to large changes in electromagnetic absorption. Hence, the sensitivity may be optimized in a manner not previously suggested by the prior art. For example, maximum absorption may occur when the combined impedance matches the impedance of free space (377 ohms), and absorption then varies very sensitively with resistance around this value. This approach is not a routine variation in device structure, compared with conventional devices, as it allows optimization of electromagnetic response of a passive element.

End-loaded antenna configurations, particularly end-loaded dipoles, described herein are useful for analyte detection.

Novel concepts in the provisional are not limited any particular applications, such as the use of passive elements as chaff, but may also be used in other applications such as antennas, product labels, tickets, and the like.

The present methods, procedures, treatments, materials, and specific compounds described herein are exemplary, and are not intended as limitations on the scope of the invention. Changes therein and other uses will occur to those skilled in the art which are encompassed within the spirit of the invention as defined by the scope of the claims.

Having described our invention, we claim:

1. A passive element for assisting detection of the presence of an analyte, the passive element comprising:
a substrate;
a first dipole supported by the substrate;
an analyte-sensitive element associated with the first dipole,
the first dipole and the chemoresistive element providing a first absorption cross section at a detection wavelength,
the analyte-sensitive element having an electrical conductivity modified by the presence of the analyte so as to modify the first absorption cross section; and
a second dipole disposed on the surface of the substrate, the second dipole having a second absorption cross section at a reference wavelength,
the second absorption cross-section being substantially independent of the presence of the analyte.

2. The passive element of claim 1,
the first dipole comprising a first conducting strip having a first end and a second end,
the analyte-sensitive element being located proximate the first end of the first conducting strip.

3. The passive element of claim 1, the first dipole having a first electrical length, the second dipole having a second electrical length,
the first electrical length and the second electrical length being approximately equal.

4. The passive element of claim 1, the analyte-sensitive element being a chemoresistive element.

5. The passive element of claim 1, the analyte-sensitive element having a low conductivity state in the absence of the analyte and a high conductivity state in the presence of the analyte.

6. The passive element of claim 5, wherein the first absorption cross section and the second absorption cross section are approximately equal when the analyte-sensitive element is in the low conductivity state.

7. The passive element of claim 5, the low conductivity state of the analyte-sensitive element acting so as to extend the electrical length of the first dipole.

8. The passive element of claim 1, wherein the substrate is a dielectric substrate.

9. The passive element of claim 1, wherein the first and second dipoles each have a cross-dipole configuration.

10. The passive element of claim 1, wherein the first dipole comprises a meandering metal strip having an analyte-sensitive element at an end thereof.

11. A passive element for assisting detection of an analyte, the passive element comprising:
a frequency selective surface (FSS), the FSS comprising FSS elements;
a dielectric layer; and
an impedance layer comprising an analyte-sensitive material,
the dielectric layer being located between the impedance layer and the FSS,
the passive element having an absorption at a detection wavelength, the impedance layer having a sheet resistance modified by a presence of the analyte so as to modify the absorption

12. The passive element of claim 11, wherein the FSS elements are arranged in a periodic array.

13. The passive element of claim 11 wherein the analyte-sensitive material is a chemoresistive material.

14. The passive element of claim 11 wherein the impedance layer comprises a plurality of sub-layers,
a first sub-layer comprising a chemoresistive material,
a second sub-layer comprising a non-chemoresistive conducting material.

15. The passive element of claim 11, wherein the passive element further has an absorption at a reference wavelength that is substantially independent of the presence of the analyte.

16. The passive element of claim 11, wherein the detection wavelength is an IR wavelength.

17. The passive element of claim 11, wherein the passive element has a maximum absorption when the sheet resistance of the impedance layer is approximately equal to the impedance of free space.

18. The passive element of claim 11 wherein the dielectric layer has a thickness of approximately one quarter of the detection wavelength.

19. The passive element of claim 11, the FSS elements being resonant at the detection wavelength.

20. The passive element of claim 11, further comprising
a second dielectric layer; and
a second impedance layer,
the second dielectric layer being located between the FSS and the second impedance layer,
the FSS being located between the first dielectric layer and second dielectric layer.

21. The passive element of claim 20, the passive element being a sheet having first and second opposed faces,
the analyte being detectable using absorption properties of either face.

22. A method for remote passive detection of an analyte, the method comprising:
providing a passive element, the passive element including an analyte-sensitive material having an electrical conductivity modified by a presence of the analyte;
determining first absorption of the passive element at a detection wavelength,
determining a second absorption of the passive element at a reference wavelength from a passive element,
detecting the analyte from a comparison of the first absorption and the second absorption.

23. The method of claim 22, wherein the passive element includes a detection dipole and a reference dipole,
the detection dipole having an associated analyte-sensitive element.

24. The method of claim 22, wherein the passive element includes a frequency selective surface (FSS).

25. The method of claim 24, wherein the passive element further includes a dielectric layer and an impedance layer,
the dielectric layer being located between the FSS and the impedance layer,
the impedance layer comprising the analyte-sensitive material.

26. The method of claim 24, wherein the FSS includes FSS elements formed from an analyte-sensitive material.

27. The method of claim 24, wherein the FSS comprises first FSS elements and second FSS elements,
the first FSS elements having an electrical conductivity substantially independent of the presence of the analyte,
the second FSS elements having an electrical conductivity correlated with the presence of the analyte.
